(19) United States
(12) Patent Application Publication
(10) Pub. No.: US 2026/0239530 A1
(43) Pub. Date: Aug. 13, 2026

(54) MULTILAYER WIRING SUBSTRATE

(71) Applicant: Murata Manufacturing Co., Ltd., Nagaokakyo-shi (JP)

(72) Inventors: Eiichi TAKATA, Nagaokakyo-shi (JP); Toshiyuki INAOKA, Nagaokakyo-shi (JP)

(21) Appl. No.: 19/639,351

(22) Filed: Apr. 6, 2026

Related U.S. Application Data
(63) Continuation of application No. PCT/JP2024/037564, filed on Oct. 22, 2024.

(30) Foreign Application Priority Data
Dec. 18, 2023 (JP) 2023-213020

(51) Int. Cl. H05K 1/03; H05K 1/11; H05K 1/181; H05K 3/46

(52) U.S. Cl. CPC H05K 1/0373; H05K 1/116; H05K 1/181; H05K 3/4644; H05K 2201/0129; H05K 2201/0209; H05K 2201/09472; H05K 2201/09527; H05K 2201/09618

(57) ABSTRACT

A multilayer wiring substrate includes an inner layer including insulating resin layers stacked in a thickness direction and including a wiring layer including a conductor pattern on a surface thereof, and a surface layer including an insulating resin layer bonded to a surface of the inner layer in the thickness direction. A bonding interface between the insulating resin layer of the inner layer and the insulating resin layer of the surface layer includes unevenness. The surface layer further includes interlayer connection conductors penetrating the insulating resin layer of the surface layer in the thickness direction and electrically connected to the wiring layer of the inner layer. The interlayer connection conductors of the surface layer include first and second surface-layer via conductors. The first surface-layer via conductor has a smaller dimension than the second surface-layer via conductor in the thickness direction and a radial direction.

### CROSS REFERENCE TO RELATED APPLICATIONS

This application claims the benefit of priority to Japanese Patent Application No. 2023-213020 filed on Dec. 18, 2023 and is a Continuation Application of PCT Application No. PCT/JP2024/037564 filed on Oct. 22, 2024. The entire contents of each application are hereby incorporated herein by reference.

### BACKGROUND OF THE INVENTION

### 1. Field of the Invention

The present invention relates to multilayer wiring substrates.

### 2. Description of the Related Art

International Publication No. 2018/100922 discloses a plate-shaped multilayer wiring substrate in which at least two resin layers, each including an insulating base and a conductive pattern provided on the insulating base, are stacked on top of each other, and a surface layer having a higher elastic modulus than the insulating base is bonded onto the resin layers stacked. The multilayer wiring substrate includes a bonding interface between the resin layer and the surface layer with unevenness.

International Publication No. 2018/100922 states that since the resin layer has surface unevenness, the surface layer is less likely to peel off from the resin layer due to differences in thermal expansion coefficients or impact, and it is possible to obtain a highly-reliable multilayer wiring substrate with a flat surface.

International Publication No. 2018/100922 states that interlayer connection conductors that penetrate the surface layer may be provided. In such a multilayer wiring substrate, by reducing the diameter of the interlayer connection conductors of the surface layer, the interlayer connection conductors can be arranged at a fine pitch. This enables high-density wiring and allows electronic components to be mounted on top at high density.

In the multilayer wiring substrate described in International Publication No. 2018/100922, however, a conductive pattern is provided on the uneven surface of the resin layer. This results in differences in distances from the substrate surface to the conductive pattern, and thus differences in the lengths of the interlayer connection conductors penetrating the surface layer. Therefore, in areas where the distance from the substrate surface to the conductive pattern is long, that is, in areas where the interlayer connection conductor penetrating the surface layer is long, reducing the diameter of the interlayer connection conductor makes it difficult to ensure connection reliability between the interlayer connection conductor and the conductive pattern.

### SUMMARY OF THE INVENTION

Example embodiments of the present invention provide multilayer wiring substrates each with high connection reliability between a wiring layer of an inner layer and an interlayer connection conductor of a surface layer even when an insulating resin layer of the inner layer includes surface unevenness.

A multilayer wiring substrate according to an example embodiment of the present invention is a plate-shaped multilayer wiring substrate that includes an inner layer including at least two insulating resin layers stacked in a thickness direction, the at least two insulating resin layers each including a wiring layer including a conductor pattern on a surface thereof, and a surface layer including an insulating resin layer bonded to at least one surface of the inner layer in the thickness direction. A bonding interface between the insulating resin layer of the inner layer and the insulating resin layer of the surface layer includes unevenness. At least one of the surface layers further includes interlayer connection conductors penetrating the insulating resin layer of the surface layer in the thickness direction and being electrically connected to the wiring layer of the inner layer. The interlayer connection conductors of the surface layer include a first surface-layer via conductor and a second surface-layer via conductor. The first surface-layer via conductor has a smaller dimension than the second surface-layer via conductor in both of the thickness direction and a radial direction perpendicular or substantially perpendicular to the thickness direction.

Example embodiments of the present invention provide multilayer wiring substrates each with high connection reliability between a wiring layer of an inner layer and an interlayer connection conductor of a surface layer even when an insulating resin layer of the inner layer includes surface unevenness.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a cross-sectional view schematically illustrating an example of a multilayer wiring substrate according to a first example embodiment of the present invention.

FIG. 2 is a cross-sectional view schematically illustrating a first modification of the multilayer wiring substrate according to the first example embodiment of the present invention.

FIG. 3 is a cross-sectional view schematically illustrating a second modification of the multilayer wiring substrate according to the first example embodiment of the present invention.

FIG. 4 is a cross-sectional view schematically illustrating an example of a process for preparing insulating resin layers, each including a wiring layer on a surface thereof.

FIG. 5 is a cross-sectional view schematically illustrating an example of a process for stacking insulating resin layers, each including a wiring layer on the surface thereof.

FIG. 6 is a cross-sectional view schematically illustrating an example of a process for forming an insulating resin layer of a surface layer.

FIG. 7 is a cross-sectional view schematically illustrating an example of a process for forming through holes in an insulating resin layer of the surface layer.

FIG. 8 is a cross-sectional view schematically illustrating an example of a process for forming interlayer connection conductors and a wiring layer of the surface layer.

FIG. 9 is a cross-sectional view schematically illustrating an example of a process for forming a protective film.

FIG. 10 is a cross-sectional view schematically illustrating another example of a process for preparing insulating resin layers, each including a wiring layer on a surface thereof.

FIG. 11 is a cross-sectional view schematically illustrating another example of a process for stacking insulating resin layers, each including a wiring layer on the surface thereof.

FIG. 12 is a cross-sectional view schematically illustrating another example of a process for forming an insulating resin layer of a surface layer.

FIG. 13 is a cross-sectional view schematically illustrating another example of a process for forming through holes in the insulating resin layer of the surface layer.

FIG. 14 is a cross-sectional view schematically illustrating another example of a process for forming interlayer connection conductors and a wiring layer of the surface layer.

FIG. 15 is a cross-sectional view schematically illustrating another example of a process for forming a protective film.

FIG. 16 is a cross-sectional view schematically illustrating a third modification of the multilayer wiring substrate according to the first example embodiment of the present invention.

FIG. 17 is a cross-sectional view schematically illustrating an example of a multilayer wiring substrate according to a second example embodiment of the present invention.

FIG. 18 is a cross-sectional view schematically illustrating a first modification of the multilayer wiring substrate according to the second example embodiment of the present invention.

FIG. 19 is a cross-sectional view schematically illustrating a second modification of the multilayer wiring substrate according to the second example embodiment of the present invention.

### DETAILED DESCRIPTION OF THE EXAMPLE EMBODIMENTS

Example embodiments of the present invention will be described in detail below with reference to the drawings.

Multilayer wiring substrate according to example embodiments of the present invention will now be described. The present invention is not limited to the following example embodiments and may be changed as appropriate within the scope of the present invention. The present invention also encompasses combinations of a plurality of preferred configurations described in the following example embodiments.

The example embodiments described below are merely examples, and configurations described in different example embodiments may be partially replaced or combined. In the second and subsequent example embodiments, descriptions of matters common to the first example embodiment are omitted, and differences are mainly described. In particular, the same or substantially the same advantageous effects achieved by the same or corresponding configurations will not be described for each example embodiment.

In the following description, the term “multilayer wiring substrate according to an example embodiment of the present invention” will be used unless a specific example embodiment is referred to.

In the present specification, the terms indicating relationships between elements (for example, “perpendicular”, “parallel”, and “orthogonal”) and the terms indicating the shapes of elements are not intended to represent their strict meanings alone, but are intended to encompass their substantially equivalent meanings, such as, for example, meanings with differences on the order of several percent. Also, in the present specification, the term “constant” refers not only to being completely constant, but also refers to being substantially constant, such as, for example, being constant with differences on the order of several percent.

The drawings described below are schematic views, and their dimensions, aspect ratios, scales, and the like may differ from those of actual products. In the drawings, the same or corresponding portions are denoted by the same reference numerals. Also, in the drawings, the same or corresponding elements are denoted by the same reference numerals and repeated descriptions will be omitted.

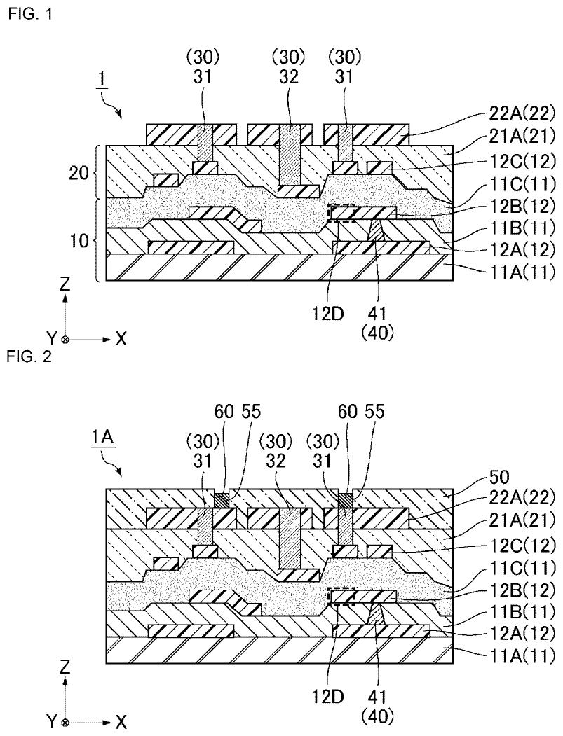

FIG. 1 is a cross-sectional view schematically illustrating an example of a multilayer wiring substrate according to a first example embodiment of the present invention. In FIG. 1, the Z-axis direction corresponds to the thickness direction, and the positive side of the Z-axis is referred to as the upper side, whereas the negative side of the Z-axis is referred to as the lower side. The same applies to the other drawings.

A multilayer wiring substrate 1 illustrated in FIG. 1 includes an inner layer 10 and a surface layer 20.

The multilayer wiring substrate 1 is plate-shaped. Being plate-shaped does not necessarily require the upper and lower surfaces to be smooth, as long as they are substantially flat.

The inner layer 10 includes at least two insulating resin layers 11 stacked in the thickness direction (Z-axis direction in FIG. 1). Each of the insulating resin layers 11 includes, on a surface thereof, a wiring layer 12 including a conductor pattern.

In the multilayer wiring substrate 1 illustrated in FIG. 1, the inner layer 10 includes, in the thickness direction, an insulating resin layer 11A including a wiring layer 12A on a surface thereof, an insulating resin layer 11B including a wiring layer 12B on a surface thereof, and an insulating resin layer 11C including a wiring layer 12C on a surface thereof. The inner layer 10 may include two, three, or four or more insulating resin layers 11. The wiring layers 12 included in the inner layer 10 may have either the same or different thicknesses.

The surface layer 20 includes an insulating resin layer 21 bonded to at least one surface of the inner layer 10 in the thickness direction. In the example embodiment illustrated in FIG. 1, the surface layer 20 includes an insulating resin layer 21A bonded to one surface of the inner layer 10 in the thickness direction (or to the upper surface of the inner layer 10 in FIG. 1). The surface layer 20 may include one insulating resin layer 21, or may include two or more insulating resin layers 21, on one surface of the inner layer 10 in the thickness direction.

The surface layer 20 preferably further includes a wiring layer 22 on a surface of the insulating resin layer 21 opposite the inner layer 10. In the example embodiment illustrated in FIG. 1, the surface layer 20 further includes a wiring layer 22A on a surface of the insulating resin layer 21A opposite the inner layer 10.

The thickness of the wiring layer 22 of the surface layer 20 may be the same as the thickness of the wiring layers 12 of the inner layer 10, greater than the thickness of the wiring layers 12 of the inner layer 10, or smaller than the thickness of the wiring layers 12 of the inner layer 10.

A bonding interface between the insulating resin layer 11 of the inner layer 10 and the insulating resin layer 21 of the surface layer 20 includes unevenness due to the influence of, for example, the wiring layers 12 of the inner layer 10. In the example embodiment illustrated in FIG. 1, a bonding interface between the insulating resin layer 11C of the inner layer 10 and the insulating resin layer 21A of the surface layer 20 includes unevenness. Of the insulating resin layers 11 of the inner layer 10, the insulating resin layer 11B and the insulating resin layer 11C include an uneven upper surface. On the other hand, the surface layer 20 includes a flat upper surface.

The surface layer 20 further includes interlayer connection conductors 30 that penetrate the insulating resin layer 21 of the surface layer 20 in the thickness direction. The interlayer connection conductors 30 of the surface layer 20 are provided to be electrically connected to the wiring layer 12 of the inner layer 10. When the surface layer 20 includes the wiring layer 22, the wiring layer 22 of the surface layer 20 is provided to be electrically connected to the interlayer connection conductors 30 of the surface layer 20. In the example embodiment illustrated in FIG. 1, the interlayer connection conductors 30 that penetrate the insulating resin layer 21A in the thickness direction are provided.

The interlayer connection conductors 30 of the surface layer 20 include a first surface-layer via conductor 31 and a second surface-layer via conductor 32.

The first surface-layer via conductor 31 is smaller in dimension than the second surface-layer via conductor 32 in both of the thickness direction and the radial direction perpendicular to the thickness direction.

In the multilayer wiring substrate 1, the first surface-layer via conductor 31 having a small radial dimension can be provided in areas where the distance between the wiring layer 12 of the inner layer 10 and the wiring layer 22 of the surface layer 20 is short. Therefore, even when the insulating resin layer 11 of the inner layer 10 includes an uneven surface, high connection reliability between the wiring layer 12 of the inner layer 10 and the interlayer connection conductor 30 of the surface layer 20 can be achieved.

Furthermore, by forming the first surface-layer via conductors 31 having a small radial dimension in the surface layer 20, high-density wiring of the wiring layer 22 of the surface layer 20 can be achieved. This allows electronic components to be mounted at high density on the surface of the multilayer wiring substrate 1.

Although a smaller radial dimension of the interlayer connection conductor 30 means higher resistance, an increase in resistance is reduced or prevented by reducing the dimension of the first surface-layer via conductor 31 in the thickness direction, so that deterioration of electrical characteristics can be reduced or prevented.

Moreover, by including the second surface-layer via conductor 32 with a large radial dimension in the interlayer connection conductors 30, the interlayer connection conductor 30 can be provided even in areas where the distance between the wiring layer 12 of the inner layer 10 and the wiring layer 22 of the surface layer 20 is long.

Since the second surface-layer via conductor 32 has a larger radial dimension than the first surface-layer via conductor 31, a lower resistance can be achieved.

In the multilayer wiring substrate 1, it is preferable that the density of the wiring layers 12 of the inner layer 10 at a position overlapping the first surface-layer via conductor 31 in the thickness direction is higher than the density of the wiring layers 12 of the inner layer 10 at a position overlapping the second surface-layer via conductor 32 in the thickness direction. In an area where the density of the wiring layers 12 of the inner layer 10 is high, the surface position of the insulating resin layer 11C of the inner layer 10 is higher than that in an area where the density of the wiring layers 12 of the inner layer 10 is low. Accordingly, in the thickness direction, the dimension of the first surface-layer via conductor 31 can be made smaller than that of the second surface-layer via conductor 32.

In the example embodiment illustrated in FIG. 1, three wiring layers 12 of the inner layer 10 are located directly below the first surface-layer via conductor 31, whereas one wiring layer 12 of the inner layer 10 is located directly below the second surface-layer via conductor 32. Accordingly, the density of the wiring layers 12 of the inner layer 10 at a position overlapping the first surface-layer via conductor 31 in the thickness direction is higher than the density of the wiring layers 12 of the inner layer 10 at a position overlapping the second surface-layer via conductor 32 in the thickness direction.

For example, as illustrated in FIG. 1, by extending the wiring layer 12B of the inner layer 10 to a position directly below the first surface-layer via conductor 31 to define a wiring layer 12D, the density of the wiring layers 12 of the inner layer 10 at a position overlapping the first surface-layer via conductor 31 in the thickness direction can be made higher than the density of the wiring layers 12 of the inner layer 10 at a position overlapping the second surface-layer via conductor 32 in the thickness direction.

In particular, it is preferable that 60<T+t×(n₁−n₂) is satisfied, where T [μm] is the total thickness of the insulating resin layer 21 of the surface layer 20, t [μm] is the thickness of one wiring layer 12 of the inner layer 10, n₁ is the number of wiring layers 12 of the inner layer 10 at a position overlapping the first surface-layer via conductor 31 in the thickness direction, and n₂ is the number of wiring layers 12 of the inner layer 10 at a position overlapping the second surface-layer via conductor 32 in the thickness direction. In this case, even when the radial dimension of the first surface-layer via conductor 31 is reduced, it is still possible to ensure connection reliability between the wiring layer 12 of the inner layer 10 and the first surface-layer via conductor 31.

The insulating resin layers 11 of the inner layer 10 are made of, for example, a thermoplastic resin, such as liquid crystal polymer (LCP), polyether ether ketone (PEEK), polyether ether ketone/polyetherimide (PEEK/PEI), perfluoroalkoxy resin (PFA), polyphenylene sulfide (PPS), thermoplastic polyimide (TPI), or polyphenylene ether (PPE). The insulating resin layers 11 of the inner layer 10 located at different positions may be made of the same type of thermoplastic resin or different types of thermoplastic resins. Even when the insulating resin layers 11 of the inner layer 10 located at different positions are made of the same type of thermoplastic resin, the compositions of the thermoplastic resins may be different.

For example, the insulating resin layers 11A, 11B, and 11C of the inner layer 10 are made of the same or different thermoplastic resins and are directly bonded by thermocompression bonding, without an adhesive made of a different material interposed therebetween. This makes the connection strength between the insulating resin layers 11 higher than that when an adhesive is interposed.

The wiring layers 12 of the inner layer 10 are made of, for example, a conductive metal, such as copper (Cu). The wiring layers 12 of the inner layer 10 may include a base layer including a metal, such as nickel (Ni), nickel chromium (NiCr), titanium (Ti), or chromium (Cr).

The inner layer 10 preferably further includes an interlayer connection conductor 40 that penetrates the insulating resin layer 11 of the inner layer 10 in the thickness direction. The interlayer connection conductor 40 of the inner layer 10 is provided so as to electrically connect the wiring layers 12 of the inner layer 10. The inner layer 10 may include the interlayer connection conductor 40 that penetrates one insulating resin layer 11 in the thickness direction, or may include the interlayer connection conductor 40 that penetrates two or more insulating resin layers 11 in the thickness direction.

The number, size, shape, arrangement, and the like of the interlayer connection conductors 40 of the inner layer 10 are not particularly limited. In the example embodiment illustrated in FIG. 1, the interlayer connection conductor 40 that penetrates the insulating resin layer 11B is provided so as to electrically connect the wiring layer 12A and the wiring layer 12B.

The interlayer connection conductor 40 of the inner layer 10 i made of, for example, a conductive metal, such as copper (Cu). The type of conductive metal of the interlayer connection conductor 40 of the inner layer 10 may be the same as, or different from, the type of conductive metal of the wiring layers 12 of the inner layer 10. The interlayer connection conductor 40 of the inner layer 10 may include a base layer including a metal, such as nickel (Ni), nickel chromium (NiCr), titanium (Ti), or chromium (Cr).

The interlayer connection conductor 40 of the inner layer 10 preferably includes a portion including a resin component. The portion including a resin component is formed, for example, by solidifying a conductive paste, such as a copper paste.

In the example embodiment illustrated in FIG. 1, the interlayer connection conductor 40 of the inner layer 10 includes a first inner-layer via conductor 41 including only a portion including a resin component.

The radial dimension of the interlayer connection conductor 40 of the inner layer 10 may be constant along the thickness direction or may vary along the thickness direction. For example, the interlayer connection conductor 40 of the inner layer 10 may have a tapered shape where the radial dimension decreases along the thickness direction. In this case, the radial dimension of the interlayer connection conductor 40 of the inner layer 10 may decrease from the lower surface toward the upper surface of the insulating resin layer 11, or may decrease from the upper surface toward the lower surface of the insulating resin layer 11.

The radial dimension of the interlayer connection conductor 40 of the inner layer 10 may be the same as the radial dimension of the interlayer connection conductor 30 of the surface layer 20, may be larger than the radial dimension of the interlayer connection conductor 30 of the surface layer 20, or may be smaller than the radial dimension of the interlayer connection conductor 30 of the surface layer 20. Specifically, the radial dimension of the interlayer connection conductor 40 of the inner layer 10 may be the same as the radial dimension of the first surface-layer via conductor 31, may be larger than the radial dimension of the first surface-layer via conductor 31, or may be smaller than the radial dimension of the first surface-layer via conductor 31. Also, the radial dimension of the interlayer connection conductor 40 of the inner layer 10 may be the same as the radial dimension of the second surface-layer via conductor 32, may be larger than the radial dimension of the second surface-layer via conductor 32, or may be smaller than the radial dimension of the second surface-layer via conductor 32. When the radial dimension of the interlayer connection conductor 40 of the inner layer 10 varies along the thickness direction, the dimension of the smallest portion is defined as the radial dimension of the interlayer connection conductor 40 of the inner layer 10. The same applies to the radial dimension of the interlayer connection conductor 30 of the surface layer 20, the first surface-layer via conductor 31, and the second surface-layer via conductor 32.

The insulating resin layer 21 of the surface layer 20 is made of, for example, a thermosetting resin, such as an epoxy resin. In this case, the insulating resin layer 21 of the surface layer 20 preferably includes a filler, such as an inorganic filler, for example. The inorganic filler may be a glass filler, such as glass fibers or spherical glass, or may be a ceramic filler, for example.

When the insulating resin layer 21 of the surface layer 20 is made of a thermosetting resin, the insulating resin layer 21 of the surface layer 20 preferably has a higher elastic modulus than the insulating resin layers 11 of the inner layer 10.

When the insulating resin layer 21 of the surface layer 20 includes a glass filler, the particle size of the glass filler may be smaller than the step height of unevenness at the bonding interface. When the particle size of the glass filler is smaller than the step height of unevenness at the bonding interface, the glass filler can be uniformly filled even in narrow regions.

When the particle size of the glass filler is smaller than the step height of unevenness at the bonding interface, a portion of the glass filler may be disposed in recesses of the bonding interface, or the entire glass filler may be disposed in recesses of the bonding interface. This can make the physical properties of the surface layer 20 uniform.

When the insulating resin layer 21 of the surface layer 20 includes a glass filler, the particle size of the glass filler may be smaller than the thickness of one wiring layer 12 of the inner layer 10. When the particle size of the glass filler is smaller than the thickness of one wiring layer 12, the glass filler can be uniformly filled even in narrow regions.

When the insulating resin layer 21 of the surface layer 20 includes a glass filler, the particle size of the glass filler may be, for example, about one-third or less of the smaller of the step height of unevenness at the bonding interface and the thickness of one wiring layer 12 of the inner layer 10. The glass filler can thus be uniformly filled even in narrow regions.

When the insulating resin layer 21 of the surface layer 20 includes a glass filler, the glass filler may be present in the thinnest portion of the insulating resin layer 21 of the surface layer 20. By uniformly filling the glass filler, the properties of the surface layer 20 can be made uniform.

When the insulating resin layer 21 of the surface layer 20 includes a glass filler, the particle size distribution of the glass filler may be either a unimodal distribution or a bimodal distribution, for example. In particular, when the particle size distribution of the glass filler is a bimodal distribution, closest packing of the glass filler can be achieved. It is thus possible to make the properties of the surface layer 20 uniform while increasing the rigidity of the surface layer 20.

The particle size of the glass filler is measured by, for example, cross-sectioning the glass filler at any location, projecting the exposed cross section with a scanning electron microscope (SEM), and measuring the size of the glass filler within the field of view. In this measurement method, the average of the maximum and minimum lengths of the cross section of the glass filler is defined as the particle size of the glass filler. The observation magnification of the SEM is, for example, about 5000 times.

The insulating resin layer 21 of the surface layer 20 may be made of, for example, a thermoplastic resin, such as liquid crystal polymer (LCP), polyether ether ketone (PEEK), polyether ether ketone/polyetherimide (PEEK/PEI), perfluoroalkoxy resin (PFA), polyphenylene sulfide (PPS), thermoplastic polyimide (TPI), or polyphenylene ether (PPE). In this case, the insulating resin layer 21 of the surface layer 20 may be made of the same type of thermoplastic resin as the insulating resin layers 11 of the inner layer 10, or may be made of a different type of thermoplastic resin from the insulating resin layers 11 of the inner layer 10. Even when the insulating resin layer 21 of the surface layer 20 is made of the same type of thermoplastic resin as the insulating resin layers 11 of the inner layer 10, the composition of the thermoplastic resin may differ from that of the insulating resin layers 11 of the inner layer 10.

The wiring layer 22 of the surface layer 20 is made of, for example, a conductive metal, such as copper (Cu). The type of conductive metal of the wiring layer 22 of the surface layer 20 may be the same as, or different from, the type of conductive metal of the wiring layers 12 of the inner layer 10. The wiring layer 22 of the surface layer 20 may include a base layer including a metal, such as nickel (Ni), nickel chromium (NiCr), titanium (Ti), or chromium (Cr).

The interlayer connection conductors 30 of the surface layer 20 are made of, for example, a conductive metal, such as copper (Cu). The type of conductive metal of the interlayer connection conductors 30 of the surface layer 20 may be the same as, or different from, the type of conductive metal of the wiring layer 22 of the surface layer 20. The type of conductive metal of the interlayer connection conductors 30 of the surface layer 20 may be the same as, or different from, the type of conductive metal of the wiring layers 12 of the inner layer 10. Further, the type of conductive metal of the interlayer connection conductors 30 of the surface layer 20 may be the same as, or different from, the type of conductive metal of the interlayer connection conductor 40 of the inner layer 10. The interlayer connection conductors 30 of the surface layer 20 may include a base layer including a metal, such as nickel (Ni), nickel chromium (NiCr), titanium (Ti), or chromium (Cr).

The interlayer connection conductors 30 of the surface layer 20 preferably include no resin component. That is, the first surface-layer via conductor 31 and the second surface-layer via conductor 32 each preferably include no resin component. In this case, for example, the content of the conductive component in the interlayer connection conductors 30 of the surface layer 20 is preferably about 90.0% by volume or more and about 100% by volume or less.

In the present specification, the phrase “including no resin component” means that the content of the resin component is about 0.1% by volume or less, for example. A portion including no resin component is formed, for example, by growing a film using, for example, a liquid phase method or a vapor phase method. For example, the portion is formed of a plating material, such as copper (Cu) plating.

The interlayer connection conductors 30 of the surface layer 20 each simply need to be provided on at least the inner wall surface of a through hole that penetrates the insulating resin layer 21 of the surface layer 20 in the thickness direction. Accordingly, the interlayer connection conductors 30 of the surface layer 20 may each be provided only on the inner wall surface of the through hole, or may be provided throughout the interior of the through hole.

The radial dimension of each of the interlayer connection conductors 30 of the surface layer 20 may be constant along the thickness direction or may vary along the thickness direction. For example, the interlayer connection conductor 30 of the surface layer 20 may have a tapered shape where the radial dimension decreases along the thickness direction. In this case, the radial dimension of the interlayer connection conductor 30 of the surface layer 20 may decrease from the lower surface toward the upper surface of the insulating resin layer 21, or may decrease from the upper surface toward the lower surface of the insulating resin layer 21.

The interlayer connection conductors 30 of the surface layer 20 may include other surface-layer via conductors, as long as they include the first surface-layer via conductor 31 and the second surface-layer via conductor 32.

FIG. 2 is a cross-sectional view schematically illustrating a first modification of the multilayer wiring substrate according to the first example embodiment of the present invention.

A multilayer wiring substrate 1A illustrated in FIG. 2 further includes a protective film 50 provided to cover the interlayer connection conductors 30 of the surface layer 20 and the wiring layer 22 of the surface layer 20. The protective film 50 is, for example, a solder resist layer.

The protective film 50 includes openings 55 through which the wiring layer 22 of the surface layer 20 (or the wiring layer 22A in FIG. 2) electrically connected to the first surface-layer via conductors 31 is exposed.

It is preferable that the openings 55 each are internally provided with an electrode 60 electrically connected to the first surface-layer via conductor 31. The electrode 60 is made of, for example, a plating material, such as gold (Au) plating.

The openings 55 may be positioned so as to overlap at least a portion of the first surface-layer via conductor 31 in the thickness direction, as illustrated on the right side of FIG. 2, or may be positioned so as not to overlap the first surface-layer via conductor 31 in the thickness direction, as illustrated on the left side of FIG. 2.

As described above, since the first surface-layer via conductors 31 can be reduced in radial dimension, the electrodes 60 can be provided at a fine pitch on the wiring layer 22 of the surface layer 20. Additionally, since the wiring layer 22 of the surface layer 20 (or the wiring layer 22A in FIG. 2) electrically connected to the first surface-layer via conductors 31 can also be reduced in area, the electrodes 60 can be provided at a fine pitch.

The multilayer wiring substrate 1A illustrated in FIG. 2 has the same or substantially the same configuration as the multilayer wiring substrate 1 illustrated in FIG. 1, except for the configuration described above.

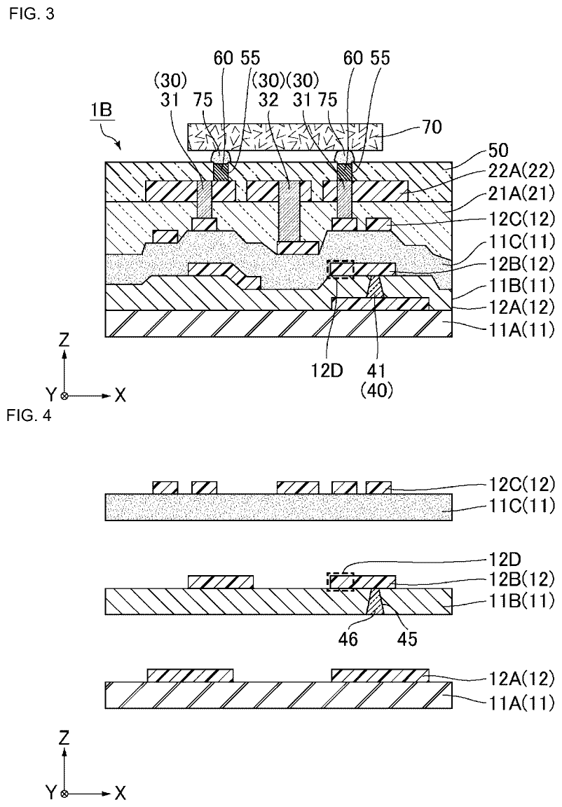

FIG. 3 is a cross-sectional view schematically illustrating a second modification of the multilayer wiring substrate according to the first example embodiment of the present invention.

A multilayer wiring substrate 1B illustrated in FIG. 3 further includes an electronic component 70 disposed on the surface of the protective film 50 and electrically connected to the first surface-layer via conductors 31. The electronic component 70 is electrically connected, for example, through solder bumps 75 to the electrodes 60. This allows the electronic component 70 to be electrically connected to the wiring layer 22 of the surface layer 20.

In the multilayer wiring substrate 1B, the upper surface of the insulating resin layer 21 of the surface layer 20 (or the insulating resin layer 21A in FIG. 3) is flat. Accordingly, the surfaces of the wiring layer 22 of the surface layer 20 and the protective film 50 are also flat. This can improve the connection reliability of the electronic component 70.

Furthermore, since the electrodes 60 can be provided at a fine pitch as in the multilayer wiring substrate 1A, the electronic component 70 with a fine electrode pitch can be mounted, or electronic components 70 can be mounted at high density.

The multilayer wiring substrate 1B illustrated in FIG. 3 has the same or substantially the same configuration as the multilayer wiring substrate 1 illustrated in FIG. 1 or the multilayer wiring substrate 1A illustrated in FIG. 2, except for the configuration described above.

The multilayer wiring substrate according to the first example embodiment of the present invention is manufactured, for example, by the following methods according to example embodiments of the present invention.

FIG. 4 is a cross-sectional view schematically illustrating an example of a process for preparing insulating resin layers, each including a wiring layer on a surface thereof.

As illustrated in FIG. 4, the insulating resin layers 11, each including the wiring layer 12 formed of a conductor pattern on the surface thereof, are prepared. The wiring layer 12 is formed, for example, by attaching a conductive material layer, such as a copper foil, to the surface of the insulating resin layer 11 and patterning the conductive material layer using photolithography and etching.

In the example illustrated in FIG. 4, the insulating resin layer 11A including the wiring layer 12A on the surface thereof, the insulating resin layer 11B including the wiring layer 12B on the surface thereof, and the insulating resin layer 11C including the wiring layer 12C on the surface thereof are prepared. On the surface of the insulating resin layer 11B, the wiring layer 12D is formed by extending the wiring layer 12B to a position directly below the first surface-layer via conductor 31 described below.

An opening 45 is provided in the insulating resin layer 11B, and a conductive paste 46, such as a copper paste, for example, is filled in the opening 45. When necessary, openings may be provided in the insulating resin layers 11A and 11C, and a conductive paste may be filled in the openings.

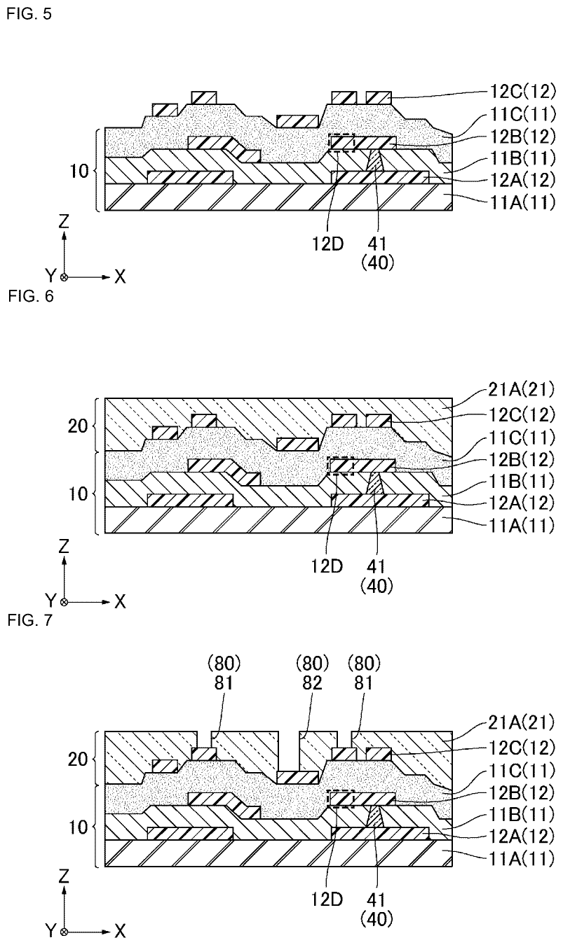

FIG. 5 is a cross-sectional view schematically illustrating an example of a process for stacking the insulating resin layers, each including a wiring layer on the surface thereof.

As illustrated in FIG. 5, the insulating resin layer 11A including the wiring layer 12A on the surface thereof is placed on a smooth table made of a hard material (not illustrated). Then, the insulating resin layer 11B including the wiring layer 12B on the surface thereof and the insulating resin layer 11C including the wiring layer 12C on the surface thereof are sequentially stacked on the insulating resin layer 11A. In this state, the stacked layers are heated to, for example, about 250° C. or higher and about 300° C. or lower, and are subjected to, for example, isostatic pressing or pseudo-isostatic pressing using hydrostatic pressure or the like. For example, the stacked layers may be pressed, with a cushioning layer, such as a silicone resin layer, placed on the insulating resin layer 11C including the wiring layer 12C on the surface thereof. When the insulating resin layers 11A, 11B, and 11C are formed of a thermoplastic resin, they are bonded to each other by being subjected to pressure in a softened state. In the process illustrated in FIG. 5, the conductive paste 46 filled in the opening 45 is also heated and cured to form the interlayer connection conductor 40 (first inner-layer via conductor 41). The first inner-layer via conductor 41 includes a resin component.

In the process illustrated in FIG. 5, the insulating resin layers 11 formed of a thermoplastic resin are softened, whereas the wiring layers 12 and the interlayer connection conductor 40 formed of, for example, a metal, such as copper, are not softened. Therefore, as illustrated in FIG. 5, the lower surface of the insulating resin layer 11 in contact with the smooth table made of a hard material is flat, whereas the upper surface of the insulating resin layer 11 includes unevenness, as the upper side of the insulating resin layer 11 subjected to pressure deforms.

The inner layer 10 is thus formed which includes at least two insulating resin layers 11 in the thickness direction, each insulating resin layer 11 including the wiring layer 12 formed of a conductor pattern on the surface thereof.

FIG. 6 is a cross-sectional view schematically illustrating an example of a process for forming an insulating resin layer of a surface layer.

As illustrated in FIG. 6, the insulating resin layer 21 is formed on the surface of the insulating resin layer 11C, with the inner layer 10 placed on the smooth table made of a hard material (not illustrated). In the example illustrated in FIG. 6, the insulating resin layer 21A is formed on one surface of the inner layer 10 in the thickness direction (or on the upper surface of the inner layer 10 in FIG. 6). As a material of the insulating resin layer 21, for example, a thermosetting resin, such as an epoxy resin or an epoxy resin including a glass filler (glass epoxy resin), is used.

By heating in this state, the insulating resin layer 21 is softened and deformed into a shape that conforms to the uneven surface of the insulating resin layer 11. Pressure is then applied to the upper surface of the insulating resin layer 21. For pressure application, for example, vacuum pressure pressing performed in a vacuum is used. In this case, it is preferable that the vacuum pressure pressing is performed, with a flat plate placed on the upper surface of the insulating resin layer 21.

As a result, as illustrated in FIG. 6, the insulating resin layer 21 of the surface layer 20 is bonded onto the insulating resin layer 11 of the inner layer 10. The upper surface of the insulating resin layer 21 of the surface layer 20 is flat. In this process, since the upper surface of the insulating resin layer 11 has an uneven shape, the bonding strength with the insulating resin layer 21 is higher than that when the upper surface of the insulating resin layer 11 is flat. When two or more insulating resin layers 21 are to be formed, the process illustrated in FIG. 6 simply needs to be repeated.

FIG. 7 is a cross-sectional view schematically illustrating an example of a process for forming through holes in the insulating resin layer of the surface layer.

As illustrated in FIG. 7, through holes 80 that penetrate the insulating resin layer 21 of the surface layer 20 in the thickness direction are formed by a method, such as laser irradiation, for example. The through holes 80 allow the wiring layer 12C of the inner layer 10 to be exposed.

The through holes 80 include a first through hole 81 and a second through hole 82.

The first through hole 81 is smaller in dimension than the second through hole 82 in both the thickness direction and the radial direction perpendicular to the thickness direction.

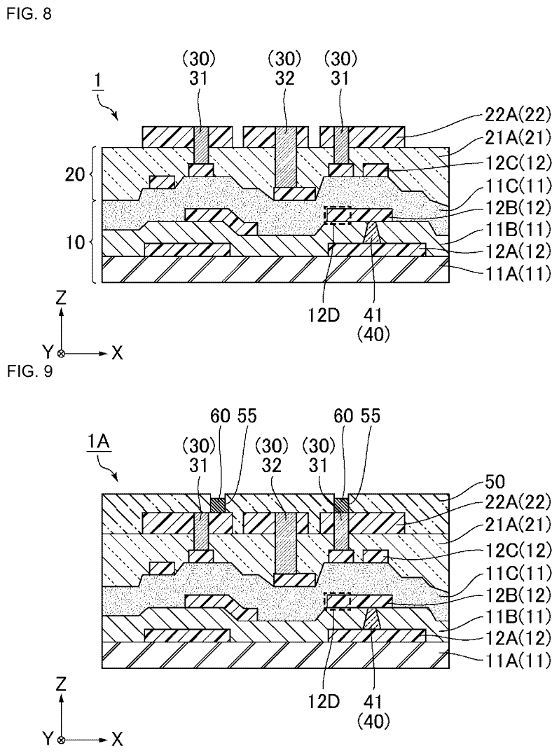

FIG. 8 is a cross-sectional view schematically illustrating an example of a process for forming interlayer connection conductors and a wiring layer of the surface layer.

As illustrated in FIG. 8, the interlayer connection conductors 30 are formed in the through holes 80. Specifically, the first surface-layer via conductor 31 is formed in the first through hole 81, and the second surface-layer via conductor 32 is formed in the second through hole 82.

Further, it is preferable that the wiring layer 22 is formed on the surface of the insulating resin layer 21 opposite to the inner layer 10. In the example illustrated in FIG. 8, the wiring layer 22A is formed on the surface of the insulating resin layer 21A opposite to the inner layer 10.

In the process illustrated in FIG. 8, the interlayer connection conductors 30 and the wiring layer 22 of the surface layer 20 can be simultaneously formed, for example, by plating, such as copper (Cu) plating.

Thus, the multilayer wiring substrate 1 is manufactured.

FIG. 9 is a cross-sectional view schematically illustrating an example of a process for forming a protective film.

As illustrated in FIG. 9, the protective film 50, such as a solder resist layer, for example, is formed to cover the interlayer connection conductors 30 of the surface layer 20 and the wiring layer 22 of the surface layer 20. The openings 55 are formed by patterning the protective film 50. The openings 55 allow the wiring layer 22 of the surface layer 20 (or the wiring layer 22A in FIG. 9) electrically connected to the first surface-layer via conductor 31 to be exposed.

In each of the openings 55, the electrode 60 electrically connected to the first surface-layer via conductor 31 is formed by, for example, plating, such as gold (Au) plating.

Thus, the multilayer wiring substrate 1A is manufactured.

While not illustrated, the electronic component 70 (see FIG. 3) may be placed on the surface of the protective film 50 so as to be electrically connected to the first surface-layer via conductor 31. Thus, the multilayer wiring substrate 1B is manufactured.

In the first manufacturing method according to the above-described example embodiment, the wiring layer 12D is formed by extending the wiring layer 12B, whereas in a second manufacturing method according to an example embodiment of the present invention, the wiring layer 12D is formed in a layer different from the wiring layer 12B.

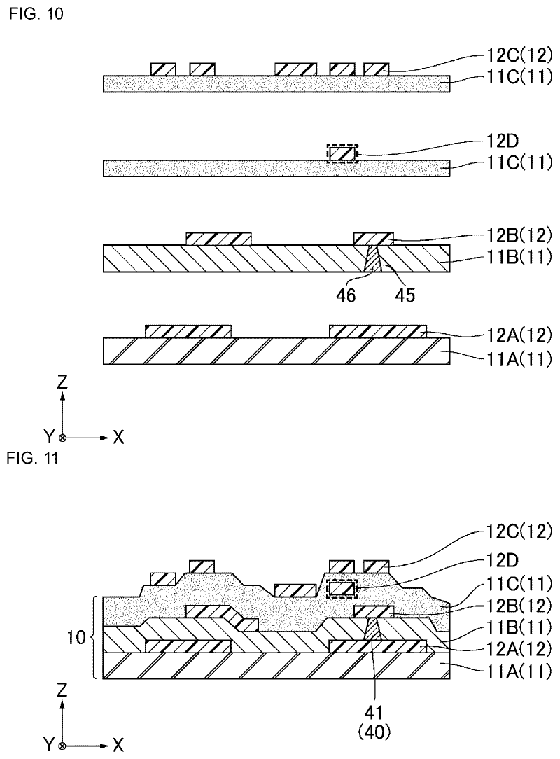

FIG. 10 is a cross-sectional view schematically illustrating another example of a process for preparing insulating resin layers, each including a wiring layer on a surface thereof.

As illustrated in FIG. 10, the insulating resin layers 11, each including the wiring layer 12 formed of a conductor pattern on the surface thereof, are prepared. The wiring layer 12 is formed, for example, by attaching a conductive material layer, such as a copper foil, to the surface of the insulating resin layer 11 and patterning the conductive material layer using photolithography and etching.

In the example illustrated in FIG. 10, the insulating resin layer 11A including the wiring layer 12A on the surface thereof, the insulating resin layer 11B including the wiring layer 12B on the surface thereof, the insulating resin layer 11C including the wiring layer 12D on the surface thereof, and the insulating resin layer 11C including the wiring layer 12C on the surface thereof are prepared. Unlike the example illustrated in FIG. 4, the insulating resin layer 11C is divided into two layers. On the surface of the insulating resin layer 11C on the lower side, the wiring layer 12D is formed at a position directly below the first surface-layer via conductor 31 described below.

The opening 45 is provided in the insulating resin layer 11B, and the conductive paste 46, such as a copper paste, for example, is filled in the opening 45. When necessary, openings may be provided in the insulating resin layers 11A and 11C, and a conductive paste may be filled in the openings.

FIG. 11 is a cross-sectional view schematically illustrating another example of a process for stacking the insulating resin layers, each having a wiring layer on the surface thereof.

As illustrated in FIG. 11, the insulating resin layer 11A including the wiring layer 12A on the surface thereof is placed on a smooth table made of a hard material (not illustrated). Then, the insulating resin layer 11B including the wiring layer 12B on the surface thereof, the insulating resin layer 11C including the wiring layer 12D on the surface thereof, and the insulating resin layer 11C including the wiring layer 12C on the surface thereof are sequentially stacked on the insulating resin layer 11A. In this state, the stacked layers are heated to, for example, about 250° C. or higher and about 300° C. or lower, and are subjected to, for example, isostatic pressing or pseudo-isostatic pressing using hydrostatic pressure or the like. For example, the stacked layers may be pressed, with a cushioning layer, such as a silicone resin layer, for example, placed on the insulating resin layer 11C including the wiring layer 12C on the surface thereof. When the insulating resin layers 11A, 11B, and 11C are formed of a thermoplastic resin, for example, they are bonded to each other by being subjected to pressure in a softened state. In the process illustrated in FIG. 11, the conductive paste 46 filled in the opening 45 is also heated and cured to form the interlayer connection conductor 40 (first inner-layer via conductor 41). The first inner-layer via conductor 41 includes a resin component.

In the process illustrated in FIG. 11, the insulating resin layers 11 formed of a thermoplastic resin are softened, whereas the wiring layers 12 and the interlayer connection conductor 40 formed of, for example, a metal, such as copper, are not softened. Therefore, as illustrated in FIG. 11, the lower surface of the insulating resin layer 11 in contact with the smooth table made of a hard material is flat, whereas the upper surface of the insulating resin layer 11 has unevenness, as the upper side of the insulating resin layer 11 subjected to pressure deforms.

The inner layer 10 is thus formed which includes at least two insulating resin layers 11 in the thickness direction, each insulating resin layer 11 having the wiring layer 12 formed of a conductor pattern on the surface thereof.

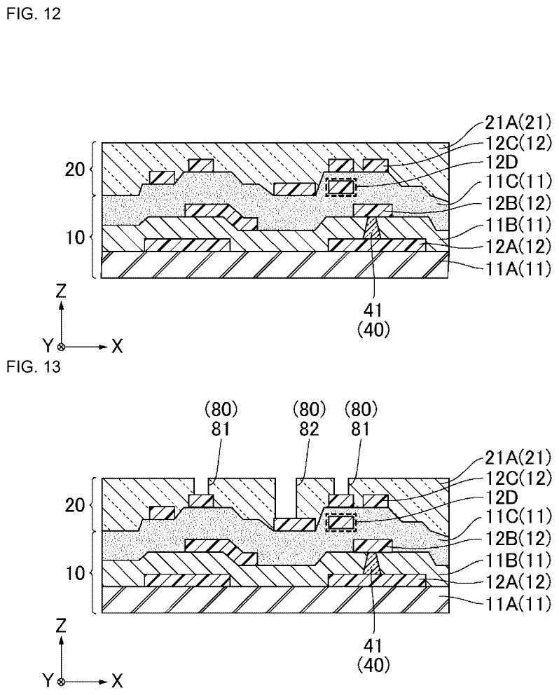

FIG. 12 is a cross-sectional view schematically illustrating another example of a process for forming an insulating resin layer of a surface layer.

As illustrated in FIG. 12, the insulating resin layer 21 is formed on the surface of the insulating resin layer 11C, with the inner layer 10 placed on the smooth table made of a hard material (not illustrated). In the example illustrated in FIG. 12, the insulating resin layer 21A is formed on one surface of the inner layer 10 in the thickness direction (or on the upper surface of the inner layer 10 in FIG. 12). As a material of the insulating resin layer 21, for example, a thermosetting resin, such as an epoxy resin or an epoxy resin including a glass filler (glass epoxy resin), is used.

By heating in this state, the insulating resin layer 21 is softened and deformed into a shape that conforms to the uneven surface of the insulating resin layer 11. Pressure is then applied to the upper surface of the insulating resin layer 21. For pressure application, for example, vacuum pressure pressing performed in a vacuum is used. In this case, it is preferable that the vacuum pressure pressing is performed, with a flat plate placed on the upper surface of the insulating resin layer 21.

As a result, as illustrated in FIG. 12, the insulating resin layer 21 of the surface layer 20 is bonded onto the insulating resin layer 11 of the inner layer 10. The upper surface of the insulating resin layer 21 of the surface layer 20 is flat. In this process, since the upper surface of the insulating resin layer 11 has an uneven shape, the bonding strength with the insulating resin layer 21 is higher than that when the upper surface of the insulating resin layer 11 is flat. When two or more insulating resin layers 21 are to be formed, the process illustrated in FIG. 12 simply needs to be repeated.

FIG. 13 is a cross-sectional view schematically illustrating another example of a process for forming through holes in the insulating resin layer of the surface layer.

As illustrated in FIG. 13, the through holes 80 that penetrate the insulating resin layer 21 of the surface layer 20 in the thickness direction are formed by a method, such as laser irradiation, for example. The through holes 80 allow the wiring layer 12C of the inner layer 10 to be exposed.

The through holes 80 include the first through hole 81 and the second through hole 82.

The first through hole 81 is smaller in dimension than the second through hole 82 in both the thickness direction and the radial direction perpendicular to the thickness direction.

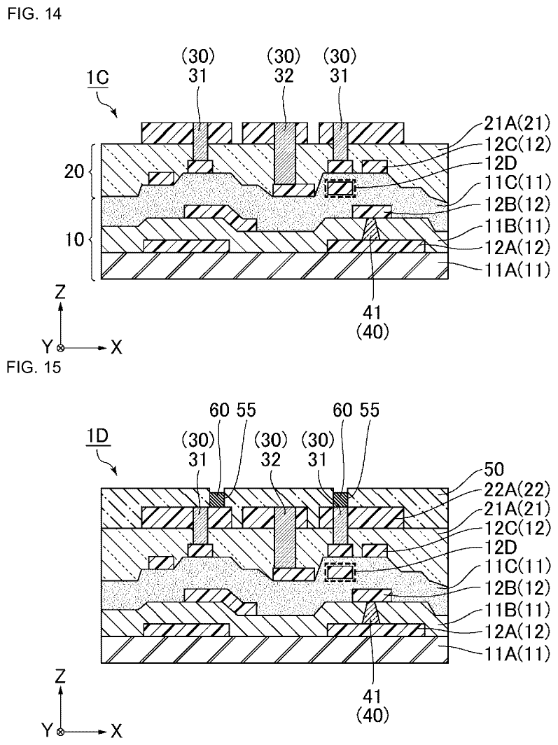

FIG. 14 is a cross-sectional view schematically illustrating another example of a process for forming interlayer connection conductors and a wiring layer of the surface layer.

As illustrated in FIG. 14, the interlayer connection conductors 30 are formed in the through holes 80. Specifically, the first surface-layer via conductor 31 is formed in the first through hole 81, and the second surface-layer via conductor 32 is formed in the second through hole 82.

Further, it is preferable that the wiring layer 22 is formed on the surface of the insulating resin layer 21 opposite to the inner layer 10. In the example illustrated in FIG. 14, the wiring layer 22A is formed on the surface of the insulating resin layer 21A opposite to the inner layer 10.

In the process illustrated in FIG. 14, the interlayer connection conductors 30 and the wiring layer 22 of the surface layer 20 can be simultaneously formed, for example, by plating, such as copper (Cu) plating.

Thus, a multilayer wiring substrate 1C is manufactured.

FIG. 15 is a cross-sectional view schematically illustrating another example of a process for forming a protective film.

As illustrated in FIG. 15, the protective film 50, such as, for example, a solder resist layer, is formed to cover the interlayer connection conductors 30 of the surface layer 20 and the wiring layer 22 of the surface layer 20. The openings 55 are formed by patterning the protective film 50. The openings 55 allow the wiring layer 22 of the surface layer 20 (or the wiring layer 22A in FIG. 15) electrically connected to the first surface-layer via conductor 31 to be exposed.

In each of the openings 55, the electrode 60 electrically connected to the first surface-layer via conductor 31 is formed by plating, such as gold (Au) plating, for example.

Thus, a multilayer wiring substrate 1D is manufactured.

While not illustrated, the electronic component 70 (see FIG. 3) may be placed on the surface of the protective film 50 so as to be electrically connected to the first surface-layer via conductor 31.

In the first manufacturing method and the second manufacturing method according to the above-described example embodiments, the insulating resin layer 21 of the surface layer 20 is formed using a thermosetting resin, whereas in a third manufacturing method according to an example embodiment of the present invention, the insulating resin layer 21 of the surface layer 20 is formed using a thermoplastic resin, for example.

For example, the insulating resin layer 11A including the wiring layer 12A on the surface thereof, the insulating resin layer 11B including the wiring layer 12B (and the wiring layer 12D) on the surface thereof, the insulating resin layer 11 including the wiring layer 12C on the surface thereof, and the insulating resin layer 21A are sequentially stacked and bonded to each other by being subjected to pressure in a softened state.

In the method described above, not only the upper surfaces of the insulating resin layers 11 of the inner layer 10, but also the upper surface of the insulating resin layer 21 of the surface layer 20 includes unevenness. Accordingly, the unevenness of the upper surface of the insulating resin layer 21 of the surface layer 20 is flattened by processing, such as polishing or grinding, for example.

Then, a multilayer wiring substrate is manufactured by the same or substantially the same process as the first manufacturing method. A multilayer wiring substrate is also manufactured by the same process as the second manufacturing method.

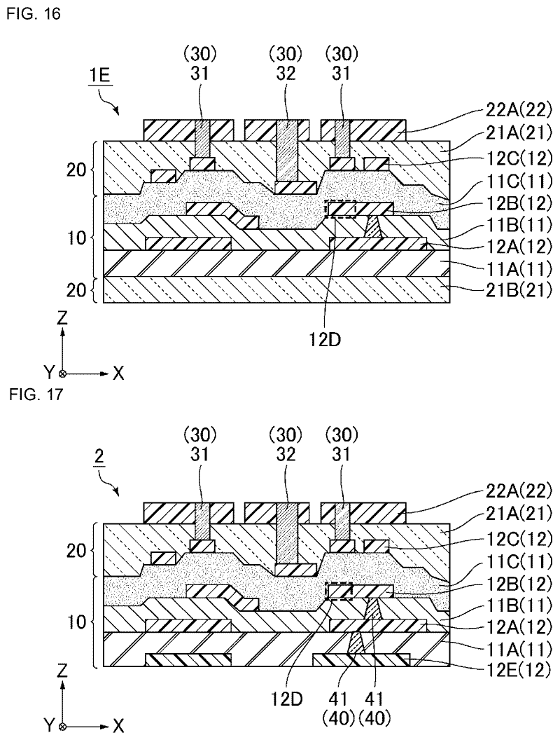

FIG. 16 is a cross-sectional view schematically illustrating a third modification of the multilayer wiring substrate according to the first example embodiment of the present invention.

In a multilayer wiring substrate 1E illustrated in FIG. 16, the surface layer 20 includes the insulating resin layer 21A bonded to one surface of the inner layer 10 in the thickness direction (or to the upper surface of the inner layer 10 in FIG. 16), and further includes an insulating resin layer 21B bonded to the other surface of the inner layer 10 in the thickness direction (or to the lower surface of the inner layer 10 in FIG. 16).

In the example embodiment illustrated in FIG. 16, the wiring layer 22A is provided on the surface of the insulating resin layer 21A opposite to the inner layer 10.

While not illustrated in FIG. 16, a wiring layer may be provided on the surface of the insulating resin layer 21B opposite to the inner layer 10. An interlayer connection conductor that penetrates the insulating resin layer 21B in the thickness direction may be provided.

In a second example embodiment of the present invention, the inner layer includes two or more interlayer connection conductors in the thickness direction. In the second example embodiment of the present invention, for example, the inner layer may include two interlayer connection conductors in the thickness direction, may include three interlayer connection conductors, or may include four or more interlayer connection conductors.

FIG. 17 is a cross-sectional view schematically illustrating an example of a multilayer wiring substrate according to the second example embodiment of the present invention.

In a multilayer wiring substrate 2 illustrated in FIG. 17, the inner layer 10 includes, in the thickness direction, the insulating resin layer 11A including the wiring layer 12A on the surface thereof, the insulating resin layer 11B including the wiring layer 12B on the surface thereof, and the insulating resin layer 11C including the wiring layer 12C on the surface thereof. The surface of the insulating resin layer 11A opposite to the wiring layer 12A is provided with a wiring layer 12E.

Further, the insulating resin layer 11A and the insulating resin layer 11B are each provided with the interlayer connection conductor 40. The interlayer connection conductor 40 penetrating the insulating resin layer 11A is provided so as to electrically connect the wiring layer 12A and the wiring layer 12E, and the interlayer connection conductor 40 penetrating the insulating resin layer 11B is provided so as to electrically connect the wiring layer 12A and the wiring layer 12B.

As described in the first example embodiment, the interlayer connection conductors 40 of the inner layer 10 each preferably include a portion including a resin component.

In the multilayer wiring substrate 2 illustrated in FIG. 17, the interlayer connection conductors 40 of the inner layer 10 each include the first inner-layer via conductor 41 including only a portion including a resin component.

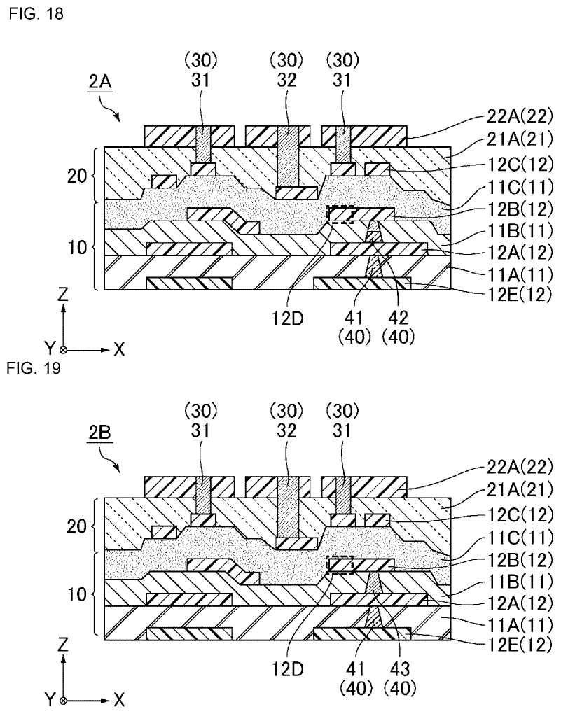

FIG. 18 is a cross-sectional view schematically illustrating a first modification of the multilayer wiring substrate according to the second example embodiment of the present invention.

In a multilayer wiring substrate 2A illustrated in FIG. 18, the interlayer connection conductors 40 of the inner layer 10 include, in addition to the first inner-layer via conductor 41 including only a portion including a resin component, a second inner-layer via conductor 42 including both a portion including a resin component and a portion including no resin component.

In the example illustrated in FIG. 18, the portion of the second inner-layer via conductor 42 including a resin component is located on the lower side, and the portion including no resin component is located on the upper side. However, the arrangement, ratio, and the like of these portions are not particularly limited. The first inner-layer via conductor 41 is located in a lower layer and the second inner-layer via conductor 42 is located in an upper layer. However, the arrangement, number, and the like thereof are not particularly limited.

FIG. 19 is a cross-sectional view schematically illustrating a second modification of the multilayer wiring substrate according to the second example embodiment of the present invention.

In a multilayer wiring substrate 2B illustrated in FIG. 19, the interlayer connection conductors 40 of the inner layer 10 include, in addition to the first inner-layer via conductor 41 including only a portion including a resin component, a third inner-layer via conductor 43 including no resin component.

In the example embodiment illustrated in FIG. 19, the first inner-layer via conductor 41 is located in a lower layer and the third inner-layer via conductor 43 is located in an upper layer. However, the arrangement, number, and the like thereof are not particularly limited.

When the inner layer 10 includes two or more interlayer connection conductors 40 in the thickness direction, the interlayer connection conductors 40 preferably overlap in the thickness direction. This enables high-density wiring. In at least one pair of interlayer connection conductors 40 adjacent in the thickness direction, at least a portion of the interlayer connection conductor 40 in the upper layer and at least a portion of the interlayer connection conductor 40 in the lower layer simply need to overlap in the thickness direction. However, it is preferable, in all of the interlayer connection conductors 40 adjacent in the thickness direction, that at least a portion of the interlayer connection conductor 40 in the upper layer overlaps at least a portion of the interlayer connection conductor 40 in the lower layer in the thickness direction.

When the inner layer 10 includes two or more interlayer connection conductors 40 in the thickness direction, the interlayer connection conductors 40 of the inner layer 10 may include only one of the first inner-layer via conductor 41, the second inner-layer via conductor 42, and the third inner-layer via conductor 43, or may include two or more of them, for example.

For example, when the interlayer connection conductors 40 include second inner-layer via conductors 42, the interlayer connection conductors 40 can be smaller in diameter and arranged at a finer pitch than when the interlayer connection conductors 40 include first inner-layer via conductors 41. Therefore, by arranging the interlayer connection conductors 40 so as to overlap each other in the thickness direction, high-density wiring can be achieved.

When the interlayer connection conductors 40 include third inner-layer via conductors 43, the interlayer connection conductors 40 can be smaller in diameter and arranged at a finer pitch. Higher-density wiring can thus be achieved.

In the first example embodiment and the second example embodiment according to the present invention, the number of the interlayer connection conductors 40 of the inner layer 10 is not particularly limited. For example, the inner layer 10 may include a plurality of interlayer connection conductors 40 in the same insulating resin layer 11. Also, the size, shape, arrangement, and the like of the interlayer connection conductors 40 of the inner layer 10 are not particularly limited. When the inner layer 10 includes a plurality of interlayer connection conductors 40, the size, shape, and the like of the interlayer connection conductors 40 may either be the same or different.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A plate-shaped multilayer wiring substrate comprising:
an inner layer including at least two insulating resin layers stacked in a thickness direction, the at least two insulating resin layers each including a wiring layer including a conductor pattern on a surface thereof; and
at least one surface layer including an insulating resin layer bonded to at least one surface of the inner layer in the thickness direction; wherein
a bonding interface between the insulating resin layer of the inner layer and the insulating resin layer of the surface layer includes unevenness;
the at least one surface layer further includes interlayer connection conductors penetrating the insulating resin layer of the surface layer in the thickness direction, the interlayer connection conductors being electrically connected to the wiring layer of the inner layer;
the interlayer connection conductors of the surface layer include a first surface-layer via conductor and a second surface-layer via conductor; and
the first surface-layer via conductor has a smaller dimension than the second surface-layer via conductor in both of the thickness direction and a radial direction perpendicular to the thickness direction.

2. The multilayer wiring substrate according to claim 1, wherein a density of the wiring layers of the inner layer at a position overlapping the first surface-layer via conductor in the thickness direction is higher than a density of the wiring layers of the inner layer at a position overlapping the second surface-layer via conductor in the thickness direction.

3. The multilayer wiring substrate according to claim 2, wherein 60<T+t×(n₁−n₂) is satisfied, where T [μm] is a total thickness of the insulating resin layer of the surface layer, t [μm] is a thickness of one of the wiring layers of the inner layer, n₁ is a number of the wiring layers of the inner layer at the position overlapping the first surface-layer via conductor in the thickness direction, and n₂ is a number of the wiring layers of the inner layer at the position overlapping the second surface-layer via conductor in the thickness direction.

4. The multilayer wiring substrate according to claim 1, wherein the first surface-layer via conductor and the second surface-layer via conductor each do not include a resin component.

5. The multilayer wiring substrate according to claim 1, wherein the inner layer further includes interlayer connection conductors penetrating the insulating resin layer of the inner layer in the thickness direction, the interlayer connection conductors electrically connecting the wiring layers of the inner layer.

6. The multilayer wiring substrate according to claim 5, wherein the interlayer connection conductors of the inner layer include a portion including a resin component.

7. The multilayer wiring substrate according to claim 5, wherein the interlayer connection conductors of the inner layer include a first inner-layer via conductor including only a portion including a resin component.

8. The multilayer wiring substrate according to claim 5, wherein the interlayer connection conductors of the inner layer include a second inner-layer via conductor including a portion including a resin component and a portion not including a resin component.

9. The multilayer wiring substrate according to claim 5, wherein the interlayer connection conductors of the inner layer include a third inner-layer via conductor not including a resin component.

10. The multilayer wiring substrate according to claim 1, wherein the at least one surface layer further includes a wiring layer on a surface of the insulating resin layer opposite to the inner layer so as to be electrically connected to the interlayer connection conductors of the surface layer.

11. The multilayer wiring substrate according to claim 10, further comprising:
a protective film covering the interlayer connection conductors of the surface layer and the wiring layer of the surface layer; wherein
the protective film includes openings through which the wiring layer of the surface layer electrically connected to the first surface-layer via conductor is exposed.

12. The multilayer wiring substrate according to claim 11, wherein at least one of the openings overlaps at least a portion of the first surface-layer via conductor in the thickness direction.

13. The multilayer wiring substrate according to claim 11, wherein at least one of the openings does not overlap the first surface-layer via conductor in the thickness direction.

14. The multilayer wiring substrate according to claim 11, further comprising an electronic component on a surface of the protective film and electrically connected to the first surface-layer via conductor.

15. The multilayer wiring substrate according to claim 1, wherein the insulating resin layer of the surface layer includes a thermosetting resin.

16. The multilayer wiring substrate according to claim 15, wherein the insulating resin layer of the surface layer includes a glass filler.

17. The multilayer wiring substrate according to claim 15, wherein the insulating resin layer of the surface layer has a higher elastic modulus than the insulating resin layers of the inner layer.

18. The multilayer wiring substrate according to claim 1, wherein the insulating resin layer of the surface layer includes a thermoplastic resin.

19. The multilayer wiring substrate according to claim 1, wherein the insulating resin layers of the inner layer include a thermoplastic resin.
